(19) United States
(12) Patent Application Publication
(10) Pub. No.: US 2012/0229181 A1
(43) Pub. Date: Sep. 13, 2012

(54) ASYNCHRONOUS CIRCUIT

(75) Inventor: Ryoichi YAMAGUCHI, Kanagawa (JP)

(73) Assignee: RENESAS ELECTRONICS CORPORATION, Kanagawa (JP)

(21) Appl. No.: 13/368,376

(22) Filed: Feb. 8, 2012

(30) Foreign Application Priority Data
Mar. 10, 2011 (JP) 2011-053097

(51) Int. Cl. H03L 7/00

(52) U.S. Cl. 327/142

(57) ABSTRACT

The asynchronous circuit includes a plurality of circuit blocks connected in a hierarchical structure, each circuit block including an arithmetic circuit and a control circuit that makes two-phase control on the arithmetic circuit, and a mode control circuit. The mode control circuit controls a circuit block in a first stage to start initialization when the circuit block starts idle phase and start working phase when a circuit block in a lowermost stage starts idle phase, and controls a circuit block in a second stage to start working phase when the circuit block in the first block starts initialization and start initialization when the circuit block in the first stage starts working phase. This improves the processing speed of a two-phase asynchronous circuit and suppresses an increase in circuit size.

### CROSS-REFERENCE TO RELATED APPLICATIONS

This application is based upon and claims the benefit of priority from Japanese patent application No. 2011-053097, filed on Mar. 10, 2011, the disclosure of which is incorporated herein in its entirety by reference.

### BACKGROUND

The present invention relates to a two-phase asynchronous circuit.

Increase in processing speed and reduction of power consumption are two issues confronted by microcomputer developers, and techniques from various points of view are proposed.

For example, Japanese Unexamined Patent Application Publication No. 63-047833 discloses a technique that allows simultaneous execution of CPU operation and instruction fetch to thereby reduce a total instruction execution time of a microcomputer.

Further, Japanese Unexamined Patent Application Publication No. 63-000749 discloses a technique that executes a data read/write cycle and an instruction code fetch cycle in parallel to thereby improve the efficiency of memory access by a bus.

As a technique to reduce the power consumption of a digital circuit of a semiconductor integrated circuit, an asynchronous design technique is known. In an asynchronous circuit according to this technique, processing timing is controlled by a handshake signal exchanged between adjacent circuit blocks, which is different from a synchronous circuit in which the entire circuit is controlled by one clock signal (global clock signal). By applying such an asynchronous circuit to a microcomputer, it is expected to reduce the power consumption of the microcomputer.

FIG. 11 illustrates the circuit shown in FIG. 27 of Japanese Unexamined Patent Application Publication No. 2008-181170 with different reference numerals. The asynchronous circuit 10 is to obtain D, which is (A+B)², from input data A and B by using two circuit blocks (the circuit block 20 and the circuit block 30). As shown therein, in the asynchronous circuit 10, the circuit block 20 includes a control circuit 22 and an arithmetic circuit 24, and the circuit block 30 includes a control circuit 32 and an arithmetic circuit 34. The arithmetic circuit 24 performs an arithmetic operation to obtain C, which is A+B, and the arithmetic circuit 34 performs an arithmetic operation to obtain D, which is C². A set of the arithmetic circuit 24 and the arithmetic circuit 34 is called a data path of the asynchronous circuit 10. Note that, although a flip-flop circuit that latches and holds an operation result is included in each arithmetic circuit, it is omitted in the figure.

The control circuit 22 and the control circuit 32 control the arithmetic circuit 24 and the arithmetic circuit 34, respectively. Specifically, when an input signal in1 is input, the control circuit 22 outputs an operation control signal mux1 to the arithmetic circuit 24. In response to the operation control signal mux1, the arithmetic circuit 24 performs an arithmetic operation A+B. After the lapse of a predetermined time corresponding to the time required for the arithmetic circuit 24 to perform the arithmetic operation, the control circuit 22 outputs a latch signal lat1 to the arithmetic circuit 24. In response to the latch signal lat1, the arithmetic circuit 24 holds the operation result. Then, the control circuit 22 outputs an output signal out1 to the circuit block 30 in the next stage. The output signal out1 is a handshake signal from the circuit block 20 to the circuit block 30, which serves as an input signal in2 to the circuit block 30.

In the circuit block 30, when the input signal in2 (output signal out1) is input, the control circuit 32 outputs an operation control signal mux2 to the arithmetic circuit 34. In response to the operation control signal mux2, the arithmetic circuit 34 performs an arithmetic operation C². After the lapse of a predetermined time corresponding to the time required for the arithmetic circuit 34 to perform the arithmetic operation, the control circuit 32 outputs a latch signal lat2 to the arithmetic circuit 34. In response to the latch signal lat2, the arithmetic circuit 34 holds the operation result. Then, the control circuit 32 outputs an output signal out2.

In general, it is necessary to perform initialization to reset the state of the arithmetic circuit to its initial state after the end of the current operation in order to start the next operation. As a control technique of the asynchronous circuit, a two-phase control scheme is known. According to this scheme, “working phase” where the effective operation of a data path such as arithmetic operation or data latch is performed and “idle phase” where a data path does not work and the initialization is performed alternately in each circuit block. In such a two-phase asynchronous circuit, control of a data path is carried out by a two-phase control circuit using a Q-module, for example (The transactions of the Institute of Electronics, Information and Communication Engineers, D-1, vol. J78, No. 4, pp. 416-423, April 1995).

In this specification, an operation performed by the entire asynchronous circuit is referred to as “process”, and an operation performed by each circuit block included in the asynchronous circuit, data transfer between registers necessary for the operation and the like are referred to as “basic operation”. Further, to simplify explanation, “basic operation” performed by a circuit block is also referred to simply as “operation”.

For example, the asynchronous circuit 10 shown in FIG. 11 executes the process D=(A+B)², and the circuit block 20 and the circuit block 30 execute the basic operation C=A+B and the basic operation D=C², respectively.

In general, the two-phase asynchronous circuit performs initialization after the end of the current operation in order to execute the next process. This is described with reference to FIG. 12.

FIG. 12 shows an example of a circuit (two-phase asynchronous circuit) that achieves the process executed by the asynchronous circuit 10 shown in FIG. 11 by using the two-phase control scheme. A two-phase asynchronous circuit 50 shown in FIG. 12 includes a circuit block 60 that performs the basic operation C=A+B, a circuit block 70 that performs the basic operation D=C², and an inverter 80 that inverts an output signal out2 output from the circuit block 70 and supplies it to the circuit block 60. The circuit block 60 includes a control circuit 62 and an arithmetic circuit 64, and the circuit block 70 includes a control circuit 72 and an arithmetic circuit 74.

When an input signal in1 is input, the control circuit 62 outputs an operation control signal mux1 to the arithmetic circuit 64, just like the control circuit 22 of the asynchronous circuit 10 shown in FIG. 11. In response to the operation control signal mux1, the arithmetic circuit 64 performs an arithmetic operation A+B. After the lapse of a predetermined time corresponding to the time required for the arithmetic circuit 64 to perform the arithmetic operation, the control circuit 62 outputs a latch signal lat1 to the arithmetic circuit 64. In response to the latch signal lat1, the arithmetic circuit 64 holds the operation result. Then, the control circuit 62 outputs an output signal out1 to the circuit block 70 in the next stage. The output signal out1 is a handshake signal from the circuit block 60 to the circuit block 70, which serves as an input signal in2 to the circuit block 70.

In the circuit block 70, when the input signal in2 (output signal out1) is input, the control circuit 72 outputs an operation control signal mux2 to the arithmetic circuit 74. In response to the operation control signal mux2, the arithmetic circuit 74 performs an arithmetic operation C². After the lapse of a predetermined time corresponding to the time required for the arithmetic circuit 74 to perform the arithmetic operation, the control circuit 72 outputs a latch signal lat2 to the arithmetic circuit 74. In response to the latch signal lat2, the arithmetic circuit 74 holds the operation result. Then, the control circuit 72 outputs an output signal out2. The output signal out2 is a handshake signal from the circuit block 70 to the circuit block 60, which is inverted by the inverter 80, and the inverted signal serves as the input signal in1 to the circuit block 60.

The control circuit of each circuit block in the two-phase asynchronous circuit 50 is described hereinafter. Note that the control circuit 62 and the control circuit 72 have the same configuration, and the control circuit 62 is described as a representative.

FIG. 13 shows an example of the control circuit 62 in the two-phase asynchronous circuit 50. As shown in FIG. 13, the control circuit 62 includes a delay element 65, an AND element 66, an inverter 67, and a Q-module 90. The input signal in1 is input to the AND element 66 and also input to the Q-module 90 through the delay element 65. Note that the delay element 65 delays only the rising edge of the input signal in1 by a predetermined length of time.

The Q-module 90 outputs the latch signal lat1 and the output signal out1. The output signal out1 is output to the circuit block in the next stage and also output to the inverter 67, inverted by the inverter 67 and then output to the AND element 66. The AND element 66 outputs the logical AND between the input signal in1 and the output signal out1 inverted by the inverter 67. The logical AND is the operation control signal mux1 to be output to the arithmetic circuit 64.

The Q-module 90 is a known one, and it includes an AND element 91, an inverter 92, a C-element 93, an AND element 94, and an inverter 95. The C-element 93 is the Muller C-element, which a storage element whose outputs reflects the input values when the all input values match.

As shown in FIG. 13, the output of the delay element 65 is input to the AND element 91 and the C-element 93. The AND element 91 outputs the logical AND between the output of the C-element 93 inverted by the inverter 92 and the output of the delay element 65. The logical AND is the latch signal lat1 to be output to the arithmetic circuit 64, and it is output to the arithmetic circuit 64 and also output to the C-element 93 and the inverter 95.

The output of the C-element 93 is input to the inverter 92 and the AND element 94. The AND element 94 outputs the logical AND between the output of the C-element 93 and the latch signal lat1 inverted by the inverter 95. The logical AND is a handshake signal (output signal out1) to the circuit block in the next stage, and it is output to the circuit block in the next stage and also output to the inverter 67.

FIG. 14 shows an example of a timing chart showing the transition of the signals in the two-phase asynchronous circuit 50 when the signals are “0” in their initial states. Note that, for easier understanding, delay between gates is not shown in FIG. 14 and timing charts used hereinbelow, except for where needed.

As shown in FIG. 14, when the input signal in1 rises at timing t0, the operation control signal mux1 also rises. In response thereto, the arithmetic circuit 64 starts operation.

At timing t1, after the lapse of time (t1−t0) corresponding to the delay of the delay element 65, the output of the delay element 65 rises to “1”. Accordingly, the latch signal lat1 also rises. In response thereto, the arithmetic circuit 64 performs latch operation and holds an operation result.

Because two inputs (the output of the delay element 65 and the latch signal lat1) to the C-element 93 have become “1”, the output of the C-element 93 transitions from “0” to “1”.

When the output of the C-element 93 becomes “1”, the signal input to the AND element 91 through the inverter 92 becomes “0”, and therefore, at timing t2, the output of the AND element 91, which is the latch signal lat1, falls.

When the latch signal lat1 falls, the output of the AND element 94, which is the output signal out1 (input signal in2), rises. In response thereto, the output of the AND element 66, which is the operation control signal mux1, falls.

Further, in response to the rising edge of the output signal out1 (input signal in2), the operation control signal mux2 rises, and the arithmetic circuit 74 starts operation.

After that, at timing t3, after the lapse of time (t3−t2) corresponding to the delay of a delay element in the control circuit 72 which is equivalent to the delay element 65 in the control circuit 62, the latch signal lat2 rises and then falls at timing t4. In response thereto, the output signal out2 rises, and the operation control signal mux2 falls.

Because the output signal out2 inverted by the inverter 80 serves as the input signal in1, the input signal in1 falls in response to the rising edge of the output signal out2 at timing t4.

In response to the falling edge of the input signal in1 at timing t4, the output of the C-element 93 transitions from “1” to “0” at timing t5, and accordingly the output signal out1 (input signal in2) falls.

In response to the falling edge of the input signal in2 at timing t5, the output of the C-element in the control circuit 72 transitions from “1” to “0” at timing t6, and accordingly the output signal out2 falls. Consequently, the input and output signals (the input signal in1, the operation control signal mux1, the latch signal lat1 and the output signal out1) of the control circuit 62 in the circuit block 60 and the input and output signals (the input signal in2, the operation control signal mux2, the latch signal lat2 and the output signal out2) of the control circuit 72 in the circuit block 70 are all “0”, and the circuit block 60 and the circuit block 70 return to their initial states.

Further, at timing t6, in response to the falling edge of the output signal out2, the input signal in1 rises. After that, at timing t6 to timing t9, the signals make the same transition as they did at timing t0 to timing t6. Further, the signals make the same transition at timing t9 to timing t11.

In FIG. 14, timing t0 to timing t2 is a period when the arithmetic circuit 64 in the circuit block 60 performs operation, which is the working phase of the circuit block 60. Further, timing t2 to timing t6 is a period when the arithmetic circuit 64 does not perform operation, which is the idle phase of the circuit block 60. Likewise, timing t2 to timing t4 is the working phase of the circuit block 70, and timing t4 to timing t7 is the idle phase of the circuit block 70.

The idle phase is to initialize the circuit block. The presence of the idle phase during which the arithmetic circuit included in the circuit block does not work causes a problem that the processing speed of the two-phase asynchronous circuit cannot increase.

Japanese Unexamined Patent Application Publication No. 2008-181170 discloses a technique of increasing the processing speed by eliminating the idle phase of the two-phase asynchronous circuit. The technique uses a control circuit 100 shown in FIG. 15, for example, in place of the control circuit (the control circuit 62, the control circuit 72) in the two-phase asynchronous circuit 50 shown in FIG. 12.

FIG. 15 shows FIG. 9 of Japanese Unexamined Patent Application Publication No. 2008-181170 with different reference numerals, and an input signal in, an output signal out, an operation control signal mux and a latch signal lat shown in FIG. 15 are respectively equivalent to the input signal in1, the output signal out1, the operation control signal mux1 and the latch signal lat1 shown in FIG. 13.

The control circuit 100 includes a req signal generation circuit 110, a delay circuit D1, a delay circuit D3, and an execution control signal generation circuit 120.

The req signal generation circuit 110 includes a C-element 112, an AND circuit 114, an inverter 116, an inverter 118, and a delay circuit D2. The execution control signal generation circuit 120 includes an OR circuit 122.

The input signal in is input to one input terminal C1 of the C-element 112 and also input to one input terminal of the AND circuit 114 through the inverter 116. The other input terminal of the AND circuit 114 is connected to an output terminal C0 of the C-element 112. The output of the AND circuit 114 is a req signal, and the req signal is input to an input terminal of the delay circuit D2, and an output terminal of the delay circuit D2 is connected to the other input terminal of the C-element 112 through the inverter 118. A signal output from the delay circuit D2, which is a signal on the input side of the inverter 118, is C2. Further, a signal on the output side of the inverter 118 is denoted hereinafter as C2_bar, though not shown.

The req signal is input to one input terminal of the OR circuit 122 and also input to the delay circuit D1. An ack signal, which is the output of the delay circuit D1, is output as the latch signal lat to an arithmetic circuit connected to the control circuit 100 and also input to the other input terminal of the OR circuit 122 and the delay circuit D3. The output of the delay circuit D3 is the output signal out to be output to the circuit block in the next stage. The output of the OR circuit 122 is the operation control signal mux to be output to the arithmetic circuit.

Note that the delay circuit D1 in the control circuit 100 delays only the falling edge of the input (which is the req signal in this example).

FIG. 16 shows FIG. 13 of Japanese Unexamined Patent Application Publication No. 2008-181170, which is a timing chart showing transition of the signals of the control circuit 100 shown in FIG. 15. In FIG. 16, arrows indicate causal relationship.

As shown in FIG. 16, at timing t0 in the initial state, the signals are “0” except for the signal C2_bar on the output side of the inverter 118.

At timing t1, when the input signal in1 rises, the two inputs of the C-element 112 become the same value “1”, and the signal C0 at the output terminal rises.

At timing t2, when the input signal in1 falls, the signal at one input terminal C1 of the C-element 112 falls; however, because the signal C2_bar at the other input terminal of the C-element 112 remains “1”, the C-element 112 holds “1” for a while. Accordingly, the output of the AND circuit 114, the req signal, rises.

After the rising edge of the req signal at timing t2, the ack signal, the operation control signal mux, the latch signal lat and the output signal out rise.

Then, at timing after the lapse of time corresponding to the delay of the delay circuit D2 from the timing t2 at which the req signal has risen, the signal C2, which is a delayed signal of the req signal, rises. In response thereto, the signal C2_bar on the output side of the inverter 118 falls.

The two inputs of the C-element 112 thereby become “0”, and accordingly, at timing t3, the signal C0 falls and the req signal also falls.

In response to the falling edge of the req signal, the signal C2 falls, and the signal C2_bar rises.

After the above operation, at timing t6, the input signal in, the output signal out, the operation control signal mux and the latch signal lat of the control circuit 100 become all “0”. The circuit block including the control circuit 100 can thereby start the next basic operation.

### SUMMARY

The present inventor has found a problem that, although the technique disclosed in Japanese Unexamined Patent Application Publication No. 2008-181170 can eliminate the idle phase, the circuit size increases. For example, as shown in FIG. 15, the control circuit 100 needs to include three delay circuits (D1, D2 and D3). The larger the number of stages of circuit blocks included in the asynchronous circuit, the larger the number of control circuits and delay circuits, which results in an increase in circuit size.

An aspect of the present invention is an asynchronous circuit. The asynchronous circuit includes a plurality of circuit blocks connected in a hierarchical structure, and each circuit block includes an arithmetic circuit and a control circuit that makes two-phase control on the arithmetic circuit.

The asynchronous circuit further includes a mode control circuit. The mode control circuit controls a circuit block in a first stage to start initialization when the circuit block starts idle phase and start working phase when a circuit block in a lowermost stage starts idle phase, and controls a circuit block in a second stage to start working phase when the circuit block in the first block starts initialization and start initialization when the circuit block in the first stage starts working phase.

The implementation of the circuit according to the above-described aspect as a method or a device, a processor including the circuit according to the above-described aspect and the like are also effective as aspects of the present invention.

According to the technique of the present invention, it is possible to improve the processing speed of a two-phase asynchronous circuit and suppress an increase in circuit size.

### BRIEF DESCRIPTION OF THE DRAWINGS

The above and other aspects, advantages and features will be more apparent from the following description of certain embodiments taken in conjunction with the accompanying drawings, in which:

FIG. 1 is a diagram showing an asynchronous circuit according to a first embodiment of the invention;

FIG. 2 is a diagram showing a circuit configuration example of a mode control circuit in the asynchronous circuit shown in FIG. 1;

FIG. 3 is another diagram showing a circuit configuration example of a mode control circuit in the asynchronous circuit shown in FIG. 1;

FIG. 4 is a diagram showing the asynchronous circuit shown in FIG. 1 to which the mode control circuit shown in FIG. 3 is applied;

FIG. 5 is a timing chart showing transition of signals in the asynchronous circuit shown in FIG. 4;

FIG. 6 is a diagram showing a microcomputer according to a second embodiment of the invention;

FIG. 7 is a timing chart showing transition of signals in an asynchronous circuit included in the microcomputer shown in FIG. 6;

FIG. 8 is a diagram showing a microcomputer including a two-phase asynchronous circuit according to related art;

FIG. 9 is a timing chart showing transition of signals in an asynchronous circuit included in the microcomputer shown in FIG. 8;

FIG. 10 is a diagram to explain a difference in processing speed between the microcomputers shown in FIGS. 6 and 8;

FIG. 11 is a diagram showing an asynchronous circuit according to related art;

FIG. 12 is a diagram showing a two-phase asynchronous circuit according to related art;

FIG. 13 is a diagram showing an example of a control circuit of each circuit block of the two-phase asynchronous circuit shown in FIG. 12;

FIG. 14 is a timing chart showing transition of signals in the two-phase asynchronous circuit shown in FIG. 12;

FIG. 15 is a diagram showing a control circuit disclosed in Japanese Unexamined Patent Application Publication No. 2008-181170; and

FIG. 16 is a timing chart showing transition of signals in the control circuit shown in FIG. 15.

### DETAILED DESCRIPTION

Embodiments of the present invention will be explained hereinbelow with reference to the drawings. The following description and the attached drawings are appropriately shortened and simplified to clarify the explanation. In the drawings, the identical reference symbols denote identical structural elements and the redundant explanation thereof is omitted as appropriate.

### First Embodiment

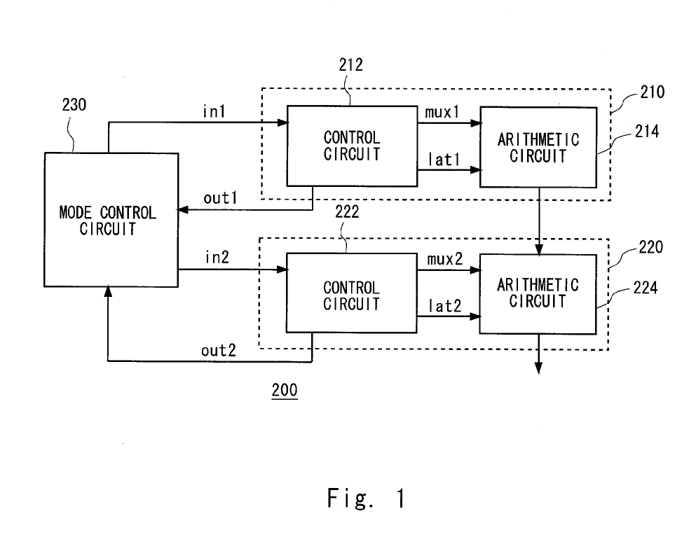

FIG. 1 shows an asynchronous circuit 200 according to a first embodiment of the invention. The asynchronous circuit 200 includes a circuit block 210 serving as a circuit block in the first stage and a circuit block 220 serving as a circuit block in the second stage. The circuit block 210 includes a control circuit 212 and an arithmetic circuit 214, and the circuit block 220 includes a control circuit 222 and an arithmetic circuit 224. The asynchronous circuit 200 is a two-phase asynchronous circuit, and the control circuit 212 and the control circuit 222 perform two-phase control on the arithmetic circuit 214 and the arithmetic circuit 224, respectively.

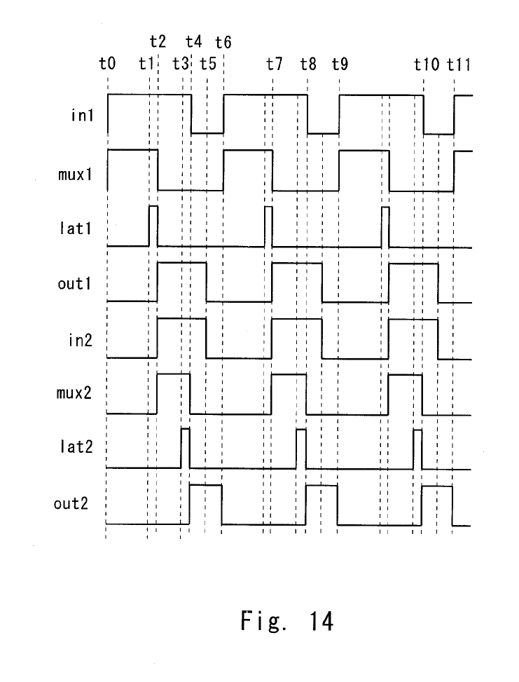

The control circuit 212 and the control circuit 222 perform the same operation as a common control circuit that makes two-phase control. For example, like the control circuit 62 shown in FIG. 13, the control circuit 212 makes the operation control signal mux1 rise at the rising edge of the signal in (input signal in1) input to the circuit block 210 to cause the arithmetic circuit 214 to start operation, thereby starting the working phase, and, after the lapse of a predetermined time, outputs the latch signal lat1 to cause a flip-flop, which is not shown, of the arithmetic circuit 214 to latch the operation result and further makes the operation control signal mux1 fall to cause the arithmetic circuit 214 to stop operation, thereby starting the idle phase. Further, simultaneously with the start of the idle phase, the control circuit 212 makes the output signal out (output signal out1) rise. Furthermore, the control circuit 212 starts initialization at the falling edge of the input signal in1, and makes the output signal out1 fall at the completion of the initialization.

Likewise, the control circuit 222 also makes the operation control signal mux2 rise at the rising edge of the signal in (input signal in2) input to the circuit block 220 to cause the arithmetic circuit 224 to start operation, thereby starting the working phase, and, after the lapse of a predetermined time, outputs the latch signal lat2 to cause a flip-flop, which is not shown, of the arithmetic circuit 224 to latch the operation result and further makes the operation control signal mux2 fall to cause the arithmetic circuit 224 to stop operation, thereby starting the idle phase. Further, simultaneously with the start of the idle phase, the control circuit 222 makes the output signal out (output signal out2) rise. Furthermore, the control circuit 222 starts initialization at the falling edge of the input signal in2, and makes the output signal out2 fall at the completion of the initialization.

The asynchronous circuit 200 further includes a mode control circuit 230. The mode control circuit 230 performs control on the circuit block in the first stage (the circuit block 210) to start initialization when the circuit block 210 starts the idle phase and start the working phase when the circuit block in the lowermost stage (which is the circuit block 220 in this example) starts the idle phase, and performs control on the circuit block in the second stage (which is the circuit block 220 in this example) to start the working phase when the circuit block in the first stage, which is the circuit block 210, starts initialization and start initialization when the circuit block 210 starts the working phase.

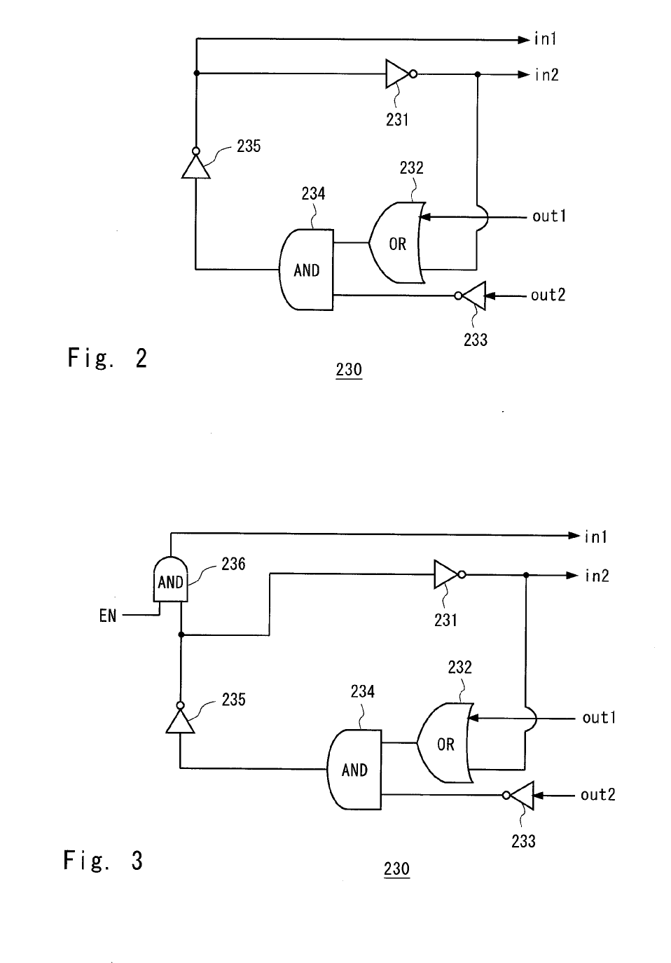

FIG. 2 shows an example of a circuit configuration of the mode control circuit 230 that achieves the above-described control. As shown in FIG. 2, the mode control circuit 230 includes an OR element 232 to which the input signal in2 of the circuit block in the second stage (the circuit block 220) and the output signal out1 of the circuit block in the first stage (the circuit block 210) are input, a first inverter 233 that inverts the output signal out2 output from the circuit block in the lowermost stage (the circuit block 220), a first AND element 234 to which outputs of the OR element 232 and the first inverter 233 are input, a second inverter 235 that inverts the output of the first AND element 234 and outputs it as the input signal in1 of the circuit block 220, and a third inverter 231 that inverts the output of the second inverter 235 and outputs it as the input signal in2.

Note that, when there is an enable signal for controlling the start and stop of the operation of the entire asynchronous circuit 200, the mode control circuit 230 can be configured as shown in FIG. 3.

The mode control circuit 230 shown in FIG. 3 further includes a second AND element 236 to which an enable signal EN and the output of the second inverter 235 are input, in addition to the circuit configuration shown in FIG. 2. In this case, the input signal in1 is the output of the second AND element 236 and input to the circuit block 210.

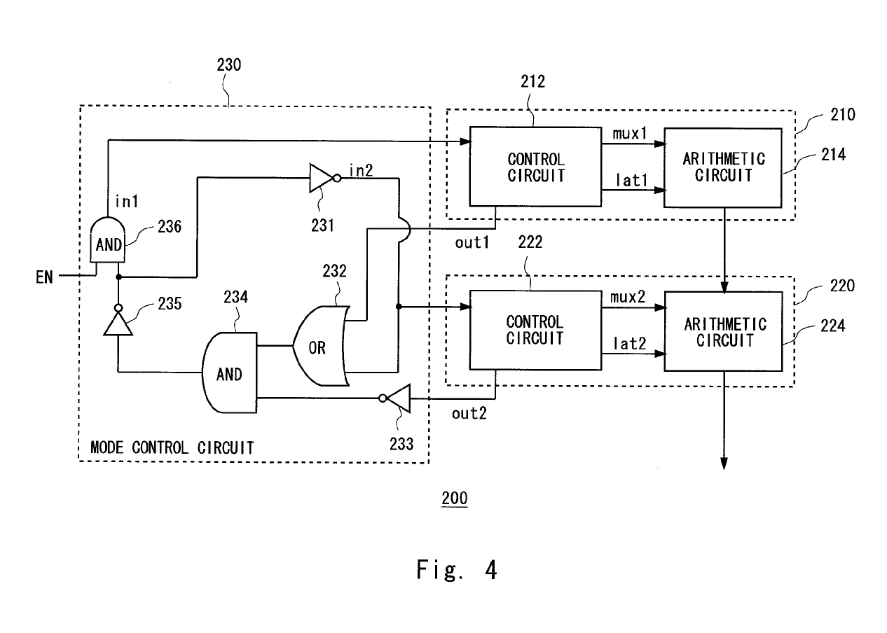

For easier understanding, the asynchronous circuit 200 to which the mode control circuit 230 shown in FIG. 3 is applied is shown in FIG. 4 as an example.

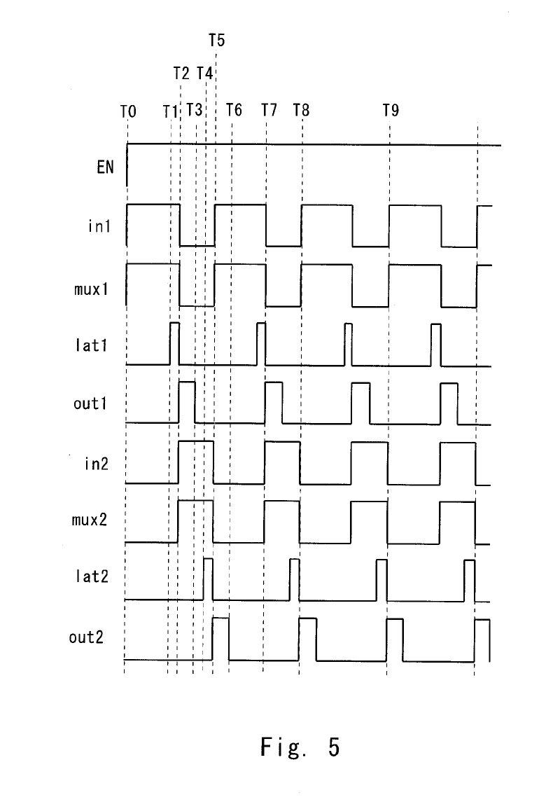

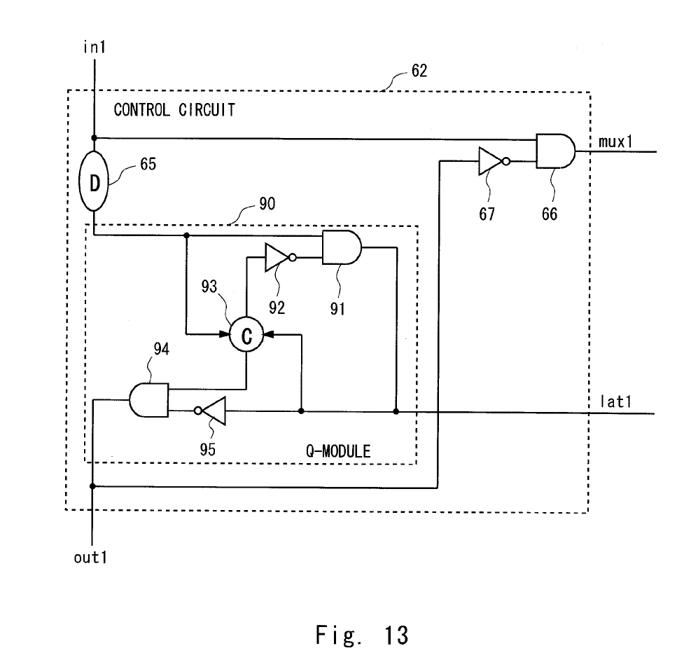

FIG. 5 is a timing chart showing transition of signals in the asynchronous circuit 200 shown in FIG. 4. For comparison with transition of signals in the two-phase asynchronous circuit 50 shown in FIG. 12, it is assumed that the arithmetic circuit 214 and the arithmetic circuit 224 in the asynchronous circuit 200 shown in FIG. 4 perform the same operation as the arithmetic circuit 64 and the arithmetic circuit 74 in the two-phase asynchronous circuit 50, respectively, and the delay elements of the control circuit 212 and the control circuit 222 in the asynchronous circuit 200 have the same delay as the delay elements of the control circuit 62 and the control circuit 72 in the two-phase asynchronous circuit 50, respectively.

Before the start of operation of the asynchronous circuit 200, the signals shown in FIG. 5 are “0”.

At timing T0, the enable signal EN rises, and the input signal in1 also rises. In response to the rising edge of the input signal in1, the operation control signal mux1 also rises, and the arithmetic circuit 214 starts operation and enters the working phase. Note that the input signal in2, which is the output of the third inverter 231, remains “0”.

At timing t1, after the lapse of time (T1−T0) corresponding to the delay of the delay element that delays only the rising edge of the input signal in the control circuit 212 from timing T0, the latch signal lat1 rises. In response thereto, the arithmetic circuit 214 performs latch operation and holds the operation result.

Then, at timing T2, the latch signal lat1 falls, the operation control signal mux1 falls, and the output signal out1 rises. The circuit block 210 thereby enters the idle phase.

When the output signal out1 rises, the output of the OR element 232 becomes “1”. Because the output signal out2 remains “0”, the output of the first inverter 233 also remains “1”. Accordingly, the output of the first AND element 234 becomes “1”, and the output of the second inverter 235 becomes “0”. Therefore, the input signal in1 falls. The control circuit 212 in the circuit block 210 thereby starts initialization. In response to the falling edge of the input signal in1 at timing T2, the output signal out1 falls at timing T3. Initialization of the control circuit 212 thereby completes.

Further, at timing T2, in response to the falling edge of the output of the second inverter 235, the input signal in2 rises. In response to the rising edge of the input signal in2, the operation control signal mux2 also rises, and the arithmetic circuit 224 starts operation and enters the working phase.

After that, at timing T4, after the lapse of time (T4−T2) corresponding to the delay of the delay element in the control circuit 222, the latch signal lat2 rises. In response thereto, the arithmetic circuit 224 performs latch operation and holds the operation result.

Then, at timing T5, the latch signal lat2 falls, the operation control signal mux2 falls, and the output signal out2 rises. The circuit block 220 thereby enters the idle phase. The first process in the asynchronous circuit 200 thereby completes.

When the output signal out2 rises, the output of the first inverter 233 becomes “0”. Accordingly, the output of the first AND element 234 becomes “0”, and the output of the second inverter 235 becomes “1”. Therefore, the input signal in2 falls, and the input signal in1 rises. The circuit block 210 thereby enters the working phase, the second process in the asynchronous circuit 200 starts, and the circuit block 220 starts initialization.

Then, at timing T6, initialization of the circuit block 220 completes, and the output signal out2 falls.

As described above, in the asynchronous circuit 200, because the circuit block 210 starts initialization simultaneously with the start of its idle phase, it is possible to start the working phase for the next process immediately when the circuit block 220 starts the idle phase.

As described earlier, in the two-phase asynchronous circuit according to related art, because the circuit block in the first stage starts initialization simultaneously with the start of the idle phase of the circuit block in the lowermost stage, the working phase for the next process is started after the lapse of a predetermined time from the start of the idle phase of the circuit block in the lowermost stage. Therefore, the mode control circuit 230 according to the embodiment of the present invention can achieve a higher processing speed than the two-phase asynchronous circuit according to related art.

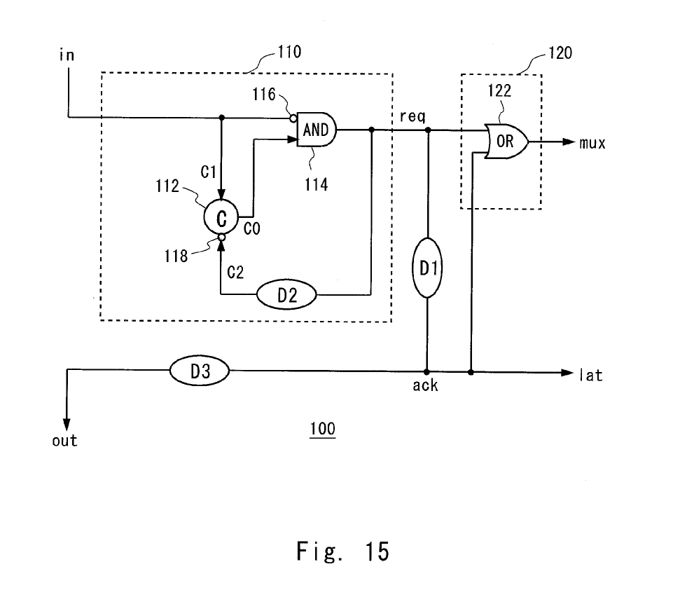

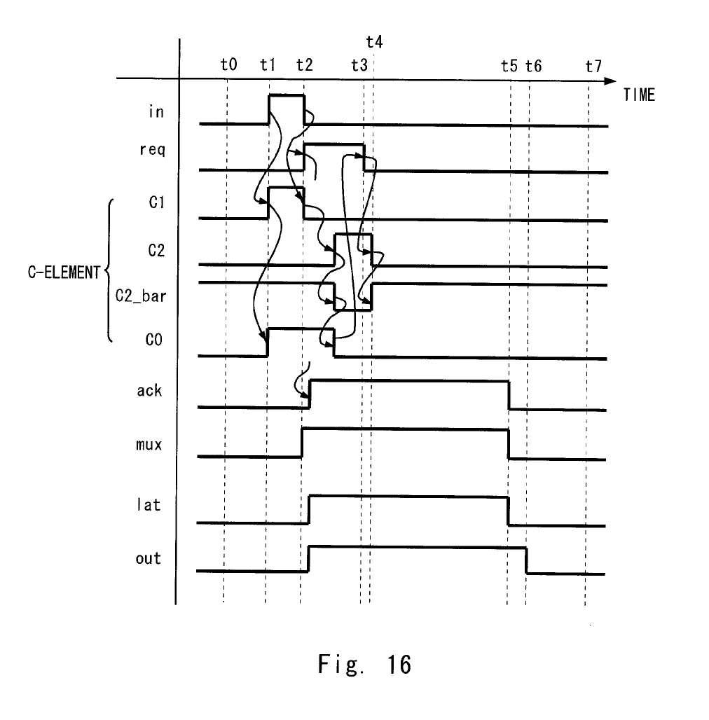

This is obvious from comparison between FIG. 5 and FIG. 14.

In FIG. 14, timing t0 to timing t2 is the working phase of the circuit block 60 in the two-phase asynchronous circuit 50 shown in FIG. 13, and timing t2 to timing t6 is the idle phase of the circuit block 60. Further, timing t2 to timing t4 is the working phase of the circuit block 70, and timing t4 to timing t7 is the idle phase of the circuit block 70.

In FIG. 5, timing t0 to timing t2 is the working phase of the circuit block 210 in the asynchronous circuit 200 shown in FIG. 4, and timing t2 to timing t5 is the idle phase of the circuit block 210. Further, timing t2 to timing t5 is the working phase of the circuit block 220, and timing t5 to timing t7 is the idle phase of the circuit block 220.

Note that the length (T2−T0) of the working phase of the circuit block 210 is the same as the length (t2−t0) of the working phase of the circuit block 60. However, the length (T5−T2) of the idle phase of the circuit block 210 is significantly shorter than the length (t6−t2) of the idle phase of the circuit block 60.

Further, the length (T5−T2) of the working phase of the circuit block 220 is the same as the length (t4−t2) of the working phase of the circuit block 70. However, the length (T7−T5) of the idle phase of the circuit block 220 is significantly shorter than the length (t7−t4) of the idle phase of the circuit block 70.

As a result, the length of time needed from the start of the current process to the start of the next process is “T5−T0” in the asynchronous circuit 200, and “t6−t0”, which is longer than “T5−T0”, in the two-phase asynchronous circuit 50. Thus, the circuit block 210 has a higher processing speed than the two-phase asynchronous circuit 50.

Further, it is only the mode control circuit 230 that is added to the asynchronous circuit 200 according to the embodiment in order to increase the processing speed, compared with a common two-phase asynchronous circuit. For example, the mode control circuit 230 shown in FIG. 2 is composed of three inverters, one OR element and one AND element, and an increase in circuit size necessary for achieving the technique disclosed in Japanese Unexamined Patent Application Publication No. 2008-181170 is small.

### Second Embodiment

In the asynchronous circuit 200 according to the first embodiment described above, the technique of the present invention is applied to a two-phase asynchronous circuit including two stages of circuit blocks. The technique of the present invention is also applicable to a two-phase asynchronous circuit including two or more stages (any number) of circuit blocks, and the above-described advantage can be obtained as well. Hereinafter, an example in which the present invention is applied to a two-phase asynchronous circuit including three or more stages of circuit blocks is described as a second embodiment.

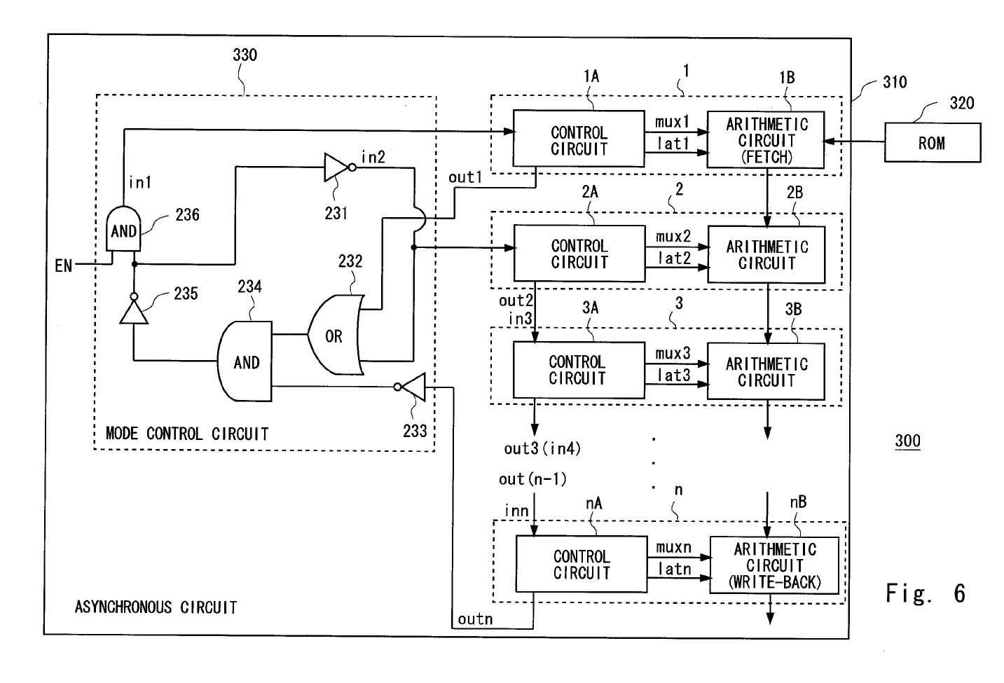

FIG. 6 is a diagram showing a microcomputer 300 according to the second embodiment of the invention. The microcomputer 300 includes an asynchronous circuit 310 that executes instructions and a ROM 320 that stores instructions and the like, and the asynchronous circuit 310 fetches instructions from the ROM 320 and executes them.

The asynchronous circuit 310 includes n (n is an integer of 3 or above) number of stages of circuit blocks 1 to n connected in a hierarchical structure and a mode control circuit 330.

Each of the circuit blocks 1 to n includes a control circuit and an arithmetic circuit. For example, the circuit block 1 includes a control circuit 1A and an arithmetic circuit 1B, the circuit block 2 includes a control circuit 2A and an arithmetic circuit 2B, the circuit block 3 includes a control circuit 3A and an arithmetic circuit 3B, and the circuit block n includes a control circuit nA and an arithmetic circuit nB.

The circuit blocks 1 to n perform the same operation as the circuit block 210 and the circuit block 220 of the asynchronous circuit 200 shown in FIG. 4. Specifically, each circuit block makes the operation control signal mux rise in response to the rising edge of the signal in input to the circuit block to cause the arithmetic circuit to start operation, thereby starting the working phase, and, after the lapse of a predetermined time, outputs the latch signal lat to cause a flip-flop, which is not shown, of the arithmetic circuit to latch the operation result and further makes the operation control signal mux fall to cause the arithmetic circuit to stop operation, thereby starting the idle phase. Further, simultaneously with the start of the idle phase, the circuit block makes the output signal out rise. Furthermore, the circuit block starts initialization at the falling edge of the input signal in, and makes the output signal out fall at the completion of the initialization.

The circuit blocks 1 to n perform fetch of an instruction, decoding of the instruction, execution of the instruction, access to memory (not shown) during execution of the instruction, write-back to memory at the completion of execution of the instruction, and the circuit blocks respectively perform the above processing.

For example, the arithmetic circuit 1B in the circuit block in the first stage (the circuit block 1) fetches an instruction from the ROM 320, and the arithmetic circuit 2B in the circuit block in the second stage (the circuit block 2) decodes the instruction fetched by the arithmetic circuit 1B. Further, the circuit block in the lowermost stage (the circuit block n) writes data back to the memory.

The mode control circuit 330 is the same as the mode control circuit 230 of the asynchronous circuit 200 shown in FIG. 4 except that an output signal outn output from the circuit block in the lowermost stage (the circuit block n) is input instead of the output signal out2 output from the circuit block in the second stage (the circuit block 2).

The mode control circuit 330 outputs the input signal in1 to the control circuit 1A of the circuit block 1. Further, the mode control circuit 330 inverts the output of the second inverter 235 by the third inverter 231 and outputs it to one input terminal of the OR element 232 and also outputs it to the control circuit 2A.

The control circuit 1A outputs the output signal out1 to the other input terminal of the OR element 232.

The control circuits of the circuit blocks in the second stage to the (n−1) stage output the output signal out to a control circuit of a circuit block in the next stage as the input signal in to the next stage. For example, as shown in FIG. 6, the control circuit 2A outputs an output signal out2 to the control circuit 3A as an input signal in3. The control circuit 3A outputs an output signal out3 to a control circuit of a circuit block in the fourth stage, which is not shown, as an input signal in4. Further, a circuit block (n−1) in the (n−1)th stage, which is not shown, outputs an output signal out(n−1) to the control circuit nA as an input signal inn to the circuit block n.

As described above, the control circuit nA of the circuit block n outputs the output signal outn to the first inverter 233 of the mode control circuit 330.

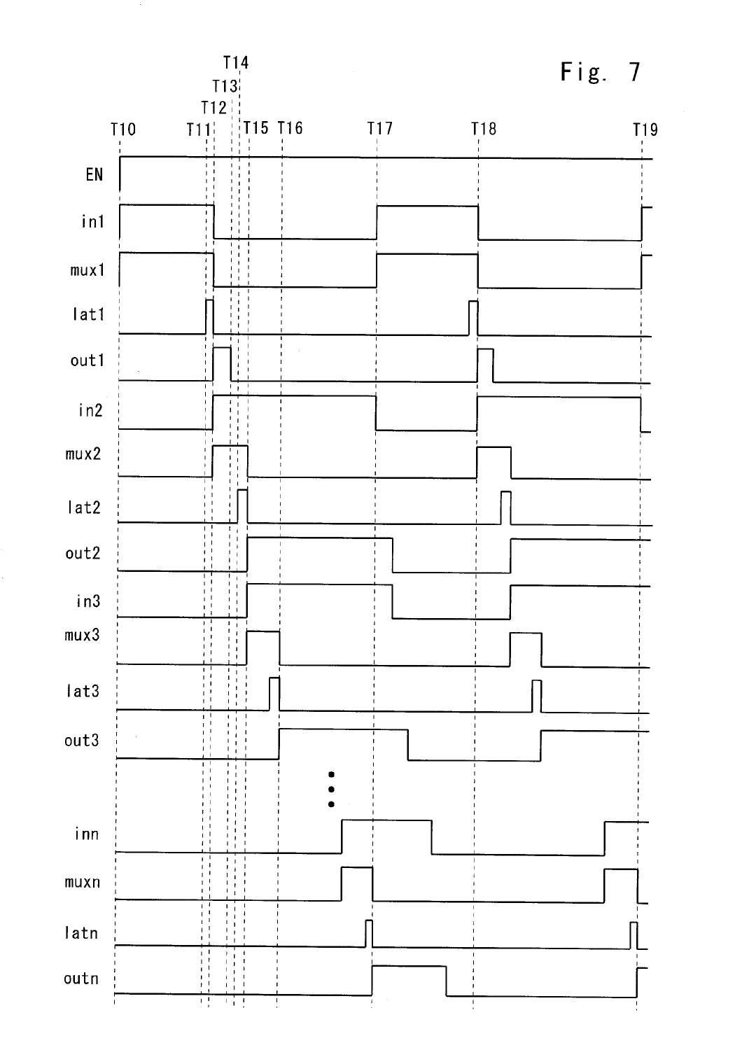

FIG. 7 is a timing chart showing transition of signals in the microcomputer 300 shown in FIG. 6.

Before the start of operation of the asynchronous circuit 310, the signals shown in FIG. 7 are “0”.

At timing T10, the enable signal EN rises, and the input signal in1 also rises. In response to the rising edge of the input signal in1, the operation control signal mux1 also rises, and the arithmetic circuit 1B starts operation (fetch in this case) and enters the working phase. Note that the input signal in2, which is the output of the third inverter 231, remains “0”.

At timing t11, after the lapse of time corresponding to the delay of the delay element in the control circuit 1A from timing T10, the latch signal lat1 rises. In response thereto, the arithmetic circuit 1B performs latch operation and holds the operation result (latched instruction).

Then, at timing T12, the latch signal lat1 falls, the operation control signal mux1 falls, and the output signal out1 rises. The circuit block 1 thereby enters the idle phase.

When the output signal out1 rises, the output of the OR element 232 becomes “1”. Because the output signal out2 remains “0”, the output of the first inverter 233 also remains “1”. Accordingly, the output of the first AND element 234 becomes “1”, and the output of the second inverter 235 becomes “0”. Therefore, the input signal in1 falls. The control circuit 1A in the circuit block 1 thereby starts initialization. Further, in response to the falling edge of the input signal in1 at timing T12, the output signal out1 falls at timing T13. Initialization of the control circuit 1A thereby completes.

Further, at timing T12, in response to the falling edge of the output of the second inverter 235, the input signal in2 rises. In response to the rising edge of the input signal in2, the operation control signal mux2 also rises, and the arithmetic circuit 2B starts operation and enters the working phase.

After that, at timing T14, after the lapse of time corresponding to the delay of the delay element in the control circuit 2A, the latch signal lat2 rises. In response thereto, the arithmetic circuit 2B performs latch operation and holds the operation result.

Then, at timing T15, the latch signal lat2 falls, the operation control signal mux2 falls, and the output signal out2 rises. The circuit block 2 thereby enters the idle phase.

When the output signal out2 rises, the input signal in3 rises. In response to the rising edge of the input signal in3, the operation control signal mux3 also rises, and the arithmetic circuit 3B starts operation and enters the working phase.

After the lapse of time corresponding to the delay of the delay element in the control circuit 3A, the latch signal lat3 rises, and the arithmetic circuit 3B performs latch operation and holds the operation result. Then, at timing T16, the latch signal lat3 falls, the operation control signal mux3 falls, and the output signal out3 rises. The circuit block 3 thereby enters the idle phase.

Circuit blocks in the subsequence stages start the working phase in response to the rising edge of the output signal out from the previous stage and, after the lapse of a predetermined time, hold the operation result and make the latch signal lat and the operation control signal mux fall and the output signal out rise, thereby entering the idle phase.

Then, at timing T17, the output signal outn from the circuit block n in the lowermost stage rises, and the circuit block n enters the idle phase.

When the output signal outn rises, the output of the first inverter 233 in the mode control circuit 330 becomes “0”. Accordingly, the output of the first AND element 234 becomes “0”, and the output of the second inverter 235 becomes “1”. Therefore, the input signal in1 rises, and the input signal in2 falls. The circuit block 1 thereby enters the working phase, the second process in the asynchronous circuit 310 starts, and the circuit block 2 starts initialization.

After that, during the period from timing T17 to T19, the same signal transition as that of timing T10 to T17 is performed. Such transition is repeated after timing T19 in the same manner.

As shown in FIG. 7, in the microcomputer 300, because the circuit block 1 in the first stage of the asynchronous circuit 310 starts initialization simultaneously with the start of its idle phase, it is possible to start the working phase for the next process immediately when the circuit block n in the lowermost stage starts the idle phase.

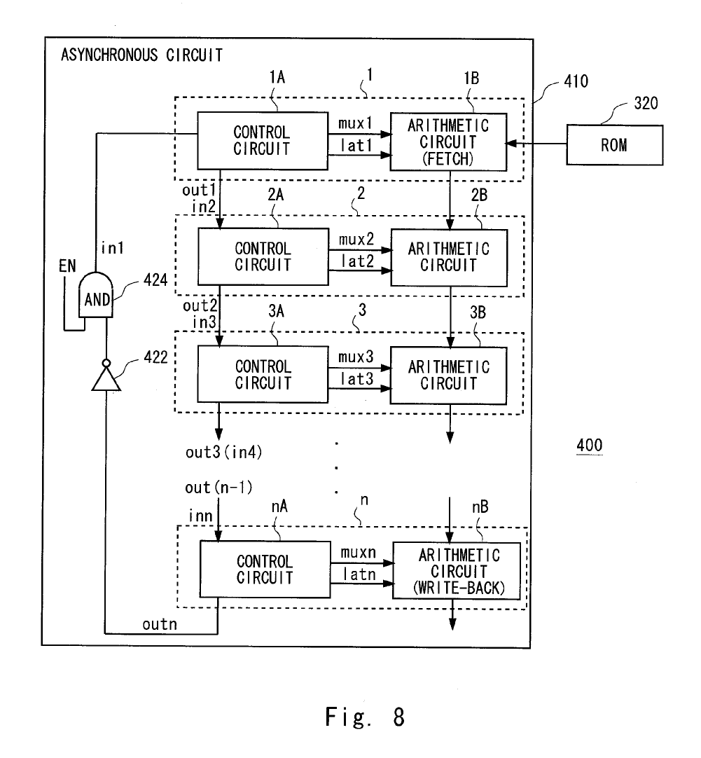

The processing speed of the microcomputer 300 and the processing speed of a microcomputer 400 shown in FIG. 8 are compared hereinbelow.

The microcomputer 400 shown in FIG. 8 includes an asynchronous circuit 410 that executes instructions and a ROM 320 that stores instructions and the like, and the asynchronous circuit 410 fetches instructions from the ROM 320 and executes them.

The asynchronous circuit 410 is a known two-phase asynchronous circuit, and n number of stages of circuit blocks (circuit blocks 1 to n) are connected in a hierarchical structure. The circuit blocks are respectively the same as the circuit blocks in the asynchronous circuit 310 of the microcomputer 300 shown in FIG. 6. However, the output signal out1 from the circuit block 1 is output to the circuit block 2 as the input signal in2 of the circuit block 2, and the output signal outn from the circuit block n in the lowermost stage is output to the inverter 422. Further, the output of the inverter 422 and the enable signal EN are input to the AND element 424, and the output of the AND element 424 serves as the input signal in1 of the circuit block 1.

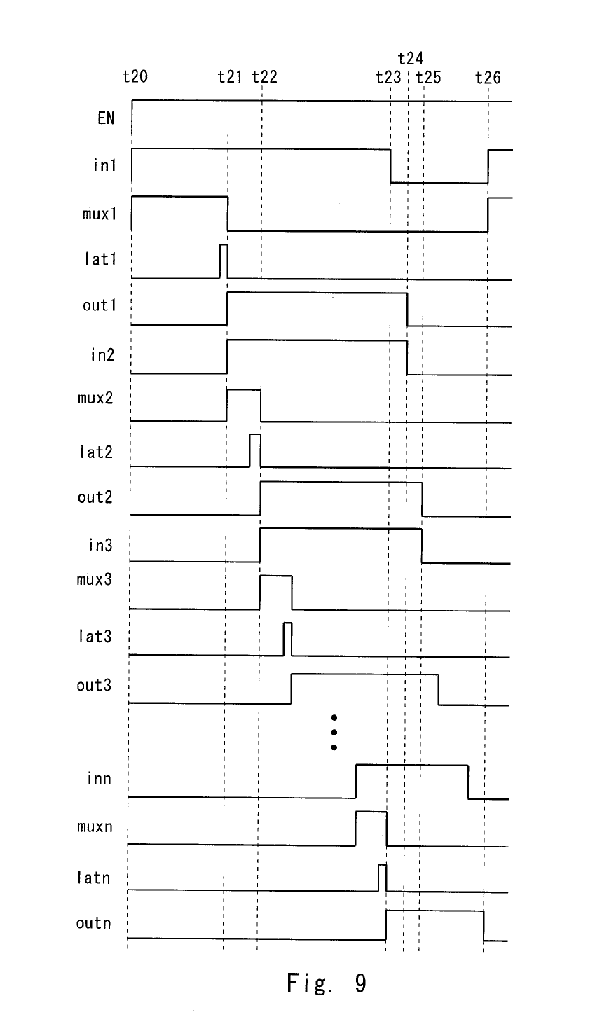

FIG. 9 is a timing chart showing transition of signals in the asynchronous circuit 400 shown in FIG. 8.

Before the start of operation of the asynchronous circuit 410, the signals shown in FIG. 8 are “0”.

At timing T20, the enable signal EN rises, and the input signal in1 also rises. In response to the rising edge of the input signal in1, the operation control signal mux1 also rises, and the arithmetic circuit 1B starts operation (fetch in this case) and enters the working phase.

After the lapse of time corresponding to the delay of the delay element in the control circuit 1A from timing T20, the latch signal lat1 rises. In response thereto, the arithmetic circuit 1B performs latch operation and holds the operation result (latched instruction).

Then, at timing T21, the latch signal lat1 falls, the operation control signal mux1 falls, and the output signal out1 rises. The circuit block 1 thereby enters the idle phase.

When the output signal out1 rises, the input signal in2 also rises. In response thereto, the operation control signal mux2 rises, and the arithmetic circuit 2B starts operation and enters the working phase.

After the lapse of time corresponding to the delay of the delay element in the control circuit 2A from timing T21, the latch signal lat2 rises. In response thereto, the arithmetic circuit 2B performs latch operation and holds the operation result.

Then, at timing T22, the latch signal lat2 falls, the operation control signal mux2 falls, and the output signal out2 rises. The circuit block 2 thereby enters the idle phase.

The circuit blocks in the subsequence stages start the working phase in response to the rising edge of the output signal out from the previous stage and, after the lapse of a predetermined time, hold the operation result and make the latch signal lat and the operation control signal mux fall and the output signal out rise, thereby entering the idle phase.

Then, at timing T23, the output signal outn from the circuit block n in the lowermost stage rises, and the circuit block n enters the idle phase.

When the output signal outn rises, the output of the inverter 422 becomes “0”. Therefore, the output of the AND element 424, which is the input signal in1, falls. The circuit block 1 thereby starts initialization.

In response to the falling edge of the input signal in1, at timing t24, the output signal out1 falls, and initialization of the circuit block 1A completes. In response thereto, the input signal in2 falls, and initialization of the control circuit 2A starts.

The subsequent circuit blocks start initialization at the completion of initialization of the circuit block in the previous stage and, at timing t26, the output signal outn falls, and initialization of the circuit block n in the lower stage completes.

When the output signal outn falls, the output of the inverter 422 becomes “1”. Therefore, the output of the AND element 424, which is the input signal in1, rises. The circuit block 1 thereby starts the next working phase.

As is obvious from comparison between FIG. 7 and FIG. 9, the length of time needed from the start of the current process to the start of the next process is “T17−T10” in the microcomputer 300 shown in FIG. 6, and “t26−t20” in the microcomputer 400 shown in FIG. 8. It is thus obvious that the processing speed of the microcomputer 300 is higher than the processing speed of the microcomputer 400.

As described above, the stage where a microcomputer such as a processor executes one instruction is typically divided into fetch of an instruction, decoding of the instruction, execution of the instruction, access to memory during execution of the instruction, and write-back to memory at the completion of execution of the instruction. The processing speeds of the microcomputer 300 shown in FIG. 6 and the microcomputer 400 shown in FIG. 8 are compared, assuming that the circuit blocks of the asynchronous circuits in the microcomputer 300 and the microcomputer 400 respectively perform the processing of the above-described stages. Note that, in this case, the number of stages of circuit blocks is n=5.

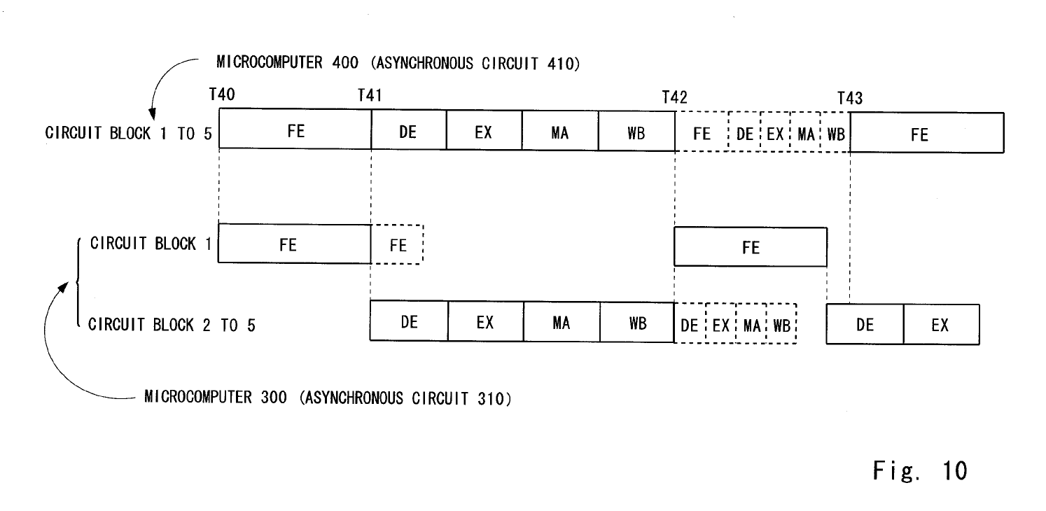

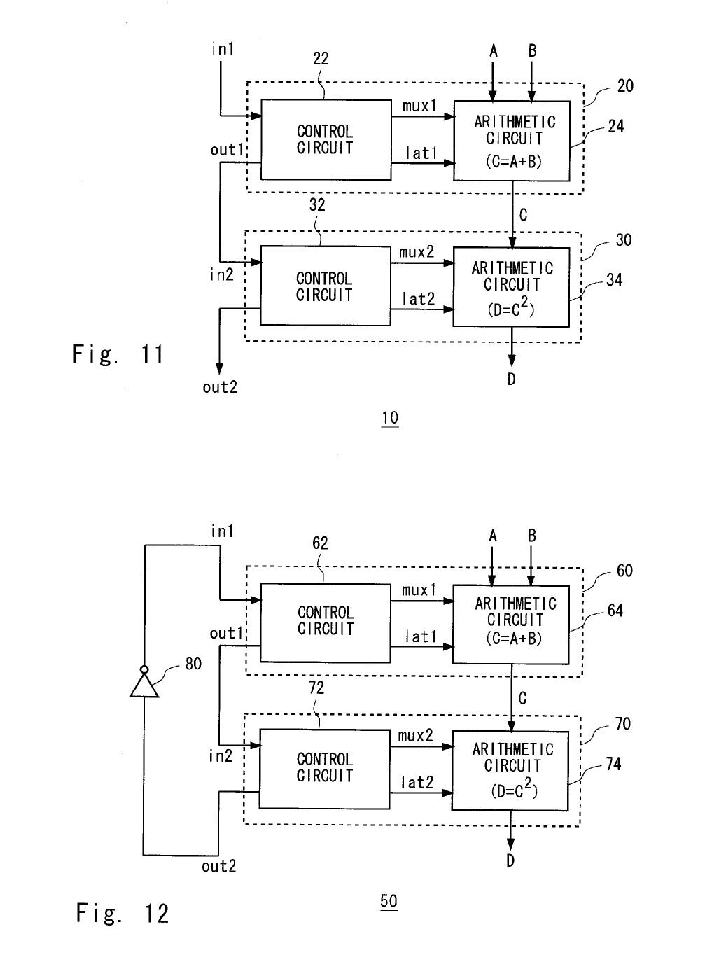

In FIG. 10, FE, DE, EX, MA and WB respectively indicate “fetch of instruction”, “decoding of instruction”, “execution of instruction”, “memory access”, and “write-back to memory”. Further, the full line indicates that the circuit block performing processing of the stage is in the working phase, and the dotted line indicates that the circuit block performing processing of the stage is under initialization.

First, at timing T40, the circuit block 1 of the asynchronous circuit 410 of the microcomputer 400 starts the working phase and fetches an instruction. Likewise, at timing T40, the circuit block 1 of the asynchronous circuit 310 of the microcomputer 300 starts the working phase and fetches an instruction.

At timing T41, the circuit block 1 of the asynchronous circuit 410 completes instruction fetch processing and enters the idle phase. Likewise, the circuit block 1 of the asynchronous circuit 310 completes instruction fetch processing and enters the idle phase.

In the case of the asynchronous circuit 410, at timing T41 when the circuit block 1 enters the idle phase, the circuit blocks 2 to 5 sequentially enter the working phase. Thus, decoding of an instruction, execution of the instruction, access to a memory and write-back to the memory are sequentially performed. Then, at timing T42, the circuit block 5 in the lowermost stage completes write-back to the memory and enters the idle phase.

In the case of the asynchronous circuit 310 also, at timing T41 when the circuit block 1 enters the idle phase, the circuit blocks 2 to 5 sequentially enter the working phase, and at timing T42, the circuit block 5 in the lowermost stage completes write-back to the memory and enters the idle phase. However, in the case of the asynchronous circuit 310, the circuit block 1 further starts initialization at timing T41.

In the case of the asynchronous circuit 410, the circuit blocks 1 to 5 sequentially start initialization from timing T42. Then, at timing T43, the circuit block 5 in the lowermost stage completes initialization. In response thereto, the circuit block 1 starts the working phase and fetches an instruction.

On the other hand, in the case of the asynchronous circuit 310, because the circuit block 1 has already completed initialization at timing T42, the circuit block 1 starts the working phase and fetches an instruction at timing T42. Further, the circuit blocks 2 to 5 sequentially start initialization from timing T42. Then, at some timing before timing T43, initialization of the circuit block 5 completes. After that, at the completion of fetch processing by the circuit block 1 that has started since timing T42, the circuit block 2 enters the working phase and executes decoding of the instruction.

As shown in FIG. 10, at timing T43, the circuit block 1 starts the working phase in the asynchronous circuit 410, whereas the circuit block 1 has already completed the working phase and the circuit block 2 is in the working phase.

Specifically, in the microcomputer 300 according to the second embodiment, the asynchronous circuit 310 starts initialization simultaneously with the start of its idle phase, and starts the working phase when the circuit block 5 in the lowermost stage starts the idle phase. Further, the circuit block 2 starts the working phase when the circuit block 1 starts initialization, and starts initialization when the circuit block 1 starts the working phase. The asynchronous circuit 310 thereby achieves a higher processing speed than the asynchronous circuit 410 according to related art.

Further, “instruction fetch”, which is one of processing of the stages executed by a processor, generally takes a longer time than processing of the other stages and it is executed in the first stage. According to the microcomputer 300 of the second embodiment of the invention, during execution of fetch by the circuit block 1, initialization of the other circuit blocks can be performed, and, during execution of processing by the other circuit blocks, initialization of the circuit block 1 can be performed, so that high processing efficiency can be achieved overall.

Further, despite that the asynchronous circuit 310 in the microcomputer 300 includes three or more stages of circuit blocks, the mode control circuit 330 has the same configuration as the mode control circuit 230 in the asynchronous circuit 200 that includes only two stages of circuit blocks shown in FIG. 4. Therefore, as the number of stages of circuit blocks is larger, the technique according to the present invention is more advantageous than the technique disclosed in Japanese Unexamined Patent Application Publication No. 2008-181170 from the viewpoint of suppressing an increase in circuit size.

Embodiments of the present invention are described in the foregoing. The embodiments are provided by way of illustration only, and various changes and modifications may be made to the above-described embodiments without departing from the scope of the invention. All such changes and modifications as would be obvious to one skilled in the art are intended for inclusion within the scope of the present invention.

For example, the first and second embodiments can be combined as desirable by one of ordinary skill in the art.

Further, for example, although the control circuit 62 shown in FIG. 13 is used as a control circuit to perform two-phase control in the above-described embodiments, a control circuit having a different circuit configuration from the control circuit 62 may be used as long as it can implement the same function as the control circuit 62 shown in FIG. 13.

Furthermore, although the mode control circuit 230 shown in FIG. 2 or 3 is used as a mode control signal in the above-described embodiments, a mode control signal having a different circuit configuration which can implement the same function as the mode control circuit 230 shown in FIG. 2 or 3 may be used.

While the invention has been described in terms of several embodiments, those skilled in the art will recognize that the invention can be practiced with various modifications within the spirit and scope of the appended claims and the invention is not limited to the examples described above.

Further, the scope of the claims is not limited by the embodiments described above. Furthermore, it is noted that, Applicant's intent is to encompass equivalents of all claim elements, even if amended later during prosecution.

What is claimed is:

1. An asynchronous circuit including a plurality of circuit blocks connected in a hierarchical structure, each circuit block including an arithmetic circuit and a control circuit that makes two-phase control on the arithmetic circuit, the asynchronous circuit further comprising:
a mode control circuit that controls a circuit block in a first stage to start initialization when the circuit block starts idle phase and start working phase when a circuit block in a lowermost stage starts idle phase, and controls a circuit block in a second stage to start working phase when the circuit block in the first block starts initialization and start initialization when the circuit block in the first stage starts working phase.

2. The asynchronous circuit according to claim 1, wherein
the control circuit causes working phase to start at a rising edge of a signal In input to the circuit block and, after a lapse of a predetermined time, causes idle phase to start and makes an output signal Out rise, and causes initialization to start at a falling edge of the signal In and makes the signal Out fall at completion of initialization, and
the mode control circuit includes:
an OR element that receives the signal In input to the circuit block in the second stage and the signal Out output from the circuit block in the first stage;
a first inverter that inverts the signal Out output from the circuit block in the lowermost stage;
a first AND element that receives outputs of the OR element and the first inverter;
a second inverter that inverts an output of the first AND element and outputs an inverted result as the signal In of the circuit block in the first stage; and
a third inverter that inverts an output of the second inverter and outputs an inverted result as the signal In of the circuit block in the second stage.

3. The asynchronous circuit according to claim 1, wherein
the asynchronous circuit is included in a processor, and
the arithmetic circuit included in the circuit block in the first stage executes a fetch instruction.

4. The asynchronous circuit according to claim 2, wherein
the asynchronous circuit is included in a processor, and
the arithmetic circuit included in the circuit block in the first stage executes a fetch instruction.

5. The asynchronous circuit according to claim 2, wherein
a second AND element is further included between the second inverter and the circuit block in the first stage,
the second AND element receives an enable signal and an output of the second inverter, and
the signal In of the circuit block in the first stage is an output of the second AND element.

6. The asynchronous circuit according to claim 3, wherein
a second AND element is further included between the second inverter and the circuit block in the first stage,
the second AND element receives an enable signal and an output of the second inverter, and
the signal In of the circuit block in the first stage is an output of the second AND element.

7. The asynchronous circuit according to claim 4, wherein
a second AND element is further included between the second inverter and the circuit block in the first stage,
the second AND element receives an enable signal and an output of the second inverter, and
the signal In of the circuit block in the first stage is an output of the second AND element.
